(19) United States
(12) Patent Application Publication
(10) Pub. No.: US 2026/0016539 A1
(43) Pub. Date: Jan. 15, 2026

(54) SYSTEM AND METHOD FOR EFFICIENT BATTERY CAPACITY ESTIMATION

(71) Applicant: GM Global Technology Operations LLC, Detroit, MI (US)

(72) Inventors: Insu Chang, Troy, MI (US); Shobhit Gupta, Sterling Heights, MI (US); Su-Yang Shieh, Clawson, MI (US); Wesley Gerard Zanardelli, Rochester, MI (US)

(21) Appl. No.: 18/768,447

(22) Filed: Jul. 10, 2024

(51) Int. Cl. G01R 31/36; G01R 31/00

(52) U.S. Cl. CPC G01R 31/36; G01R 31/006

(57) ABSTRACT

A system for efficient battery capacity estimation includes vehicle with a battery, sensors, and a human-machine-interface (HMI). The vehicle has a controller that executes a battery capacity estimation (BCE) application. The BCE application performs local data collection from the sensors, transmits the data collected by the sensors to the remote servers where data conversion occurs and a data-driven BCE model is trained. Data conversion substantially reduces a size of and removes a time-dependency of the sensor data. The local vehicle portion of the BCE application receives, from the server, the data-driven model and estimates a capacity of a battery of the battery-operated device. Upon determining a battery capacity estimate, the system notifies vehicle users, via the HMI, of the current battery capacity estimate, and shares the current battery capacity estimate with additional vehicle sub-systems.

### INTRODUCTION

The present disclosure relates to battery technologies, and more specifically to systems and methods for estimating a state of charge (SoC) and battery capacity of an electric vehicle (EV) while the EV is being used.

Battery capacity estimation typically relies on Coulomb counting, however, in order to accurately provide an estimate of a battery's capacity using Coulomb counting measures relies upon fully discharging the battery. Accordingly, while current systems and methods of estimating battery capacity achieve their intended purpose, there is a need for a new and improved system and method for efficient battery capacity estimation that utilizes existing hardware, is portable and retrofittable, maintains or reduces manufacturing complexity, improves efficiency of battery capacity estimations, reduces computational efforts and computational resource utilization, provides redundancy, increases battery capacity estimation accuracy and prediction reliability.

### SUMMARY

According to several aspects, a system for efficient battery capacity estimation in a battery-operated device includes a battery-operated device having one or more batteries, one or more sensors disposed on the battery-operated device and collecting real-time information about the battery-operated device, and a human-machine interface (HMI) disposed in the battery-operated device and transmitting information to battery-operated device users. The battery-operated device has a controller with a processor, a memory, and one or more input/output (I/O) ports. The I/O ports communicate with the one or more sensors, the battery-operated device, and the HMI. The processor executes programmatic control logic stored in the memory. The programmatic control logic includes a battery capacity estimation (BCE) application. The BCE application comprises at least a first, a second, and a third control logic. The first control logic performs local data collection from the one or more sensors of the battery-operated device. The second control logic performs data conversion of the data collected by the one or more sensors, and trains a data-driven BCE model with data converted from the data collected by the one or more sensors. The data conversion reduces a size of the data collected by the one or more sensors over time from a first size to a second size substantially smaller than the first size. The data conversion removes a time-dependency of the data from the one or more sensors. The third control logic receives the data-driven model from the second control logic and estimates a capacity of a battery of the battery-operated device. Upon determining an estimate of the capacity of the battery, the system generates a notification to the battery-operated device users, via the HMI, including the current battery capacity estimate, and shares the current battery capacity estimate with additional battery-operated device sub-systems utilizing accurate battery state-of-charge (SoC) estimations.

In another aspect of the present disclosure, the first control logic further includes control logic for determining a charging status of the battery of the battery-operated device, control logic that upon determining that the battery is currently being charged continuing to monitor the charging status of the battery, and control logic that upon determining that the battery is not currently being charged, causes the one or more sensors to begin measuring dynamic battery information during an operation or cycle of the battery-operated device. The first control logic further includes control logic that at a completion of the operation or cycle of the battery-operated device, causes the one or more sensors to stop measuring dynamic battery information, and storing an operation or cycle time defining a duration of the operation or cycle.

In another aspect of the present disclosure, the dynamic battery information further includes a voltage (V), a current (I), and a temperature (T) of the battery.

In another aspect of the present disclosure, the first control logic further includes control logic for determining whether the SoC of the battery is zero, and control logic that upon determining that the SoC of the battery is greater than zero, continues to monitor the SoC of the battery until the SoC of the battery is equal to zero. The first control logic further includes control logic that upon determining that the SoC of the battery is equal to zero, charges the battery and integrating current (I) until a state of charge of the battery is equal to 1, and control logic that upon determining that the state of charge of the battery is equal to one, generates a full original battery capacity based on integration of the current (I).

In another aspect of the present disclosure, second control logic further includes control logic for determining a quantity of data sets available for training, and control logic for defining sizes of partitions for a voltage (V), a current (I), and a temperature (T) of the battery. The second control logic further includes control logic for calculating bins of the voltage (V), current (I), and temperature (T) of the battery, wherein the bins of the voltage (V), current (I), and temperature (T) of the battery are sized based on minimum and maximum values for each variable voltage (V), current (I), and temperature (T) of the battery, including control logic for obtaining voltage minimums and maximums (V_min, V_max) from battery specifications, current minimums and maximums (I_min, I_max) from battery performance data, temperature minimums and maximums (T_min, T_max) from battery operating condition information.

In another aspect of the present disclosure, the second control logic further includes control logic for determining an optimal size of the bins by minimizing a performance index according to:

$$J = {\sum }_{k = 1}^{N} {{W}_{1} ( h ( {z}_{k} - {z}_{k - 1} ) )}^{2} + {W}_{2} N ; such that {z}_{0} = V\_min , {z}_{N} = V\_max for voltage ( V ) ; that {z}_{0} = I\_min , {z}_{N} = I\_max for current ( I ) , and that {z}_{0} = T\_min , {z}_{N} = T\_max for temperature ( T ) , {z}_{k} - {z}_{k - 1} > 0 ; N \leq {N}_{max} ∈ ℕ ;$$

where N is the number of bins, W is a weighting factor. The second control logic further includes control logic for stacking the bins of voltage (V), current (I), and temperature (T) of the battery with the time duration for the operation or cycle, and the full original battery capacity.

In another aspect of the present disclosure, the second control logic further includes control logic for augmenting new data to existing data, and control logic for determining that data conversion is complete. The second control logic further includes control logic for training a data-driven BCE model by: defining hidden layers and a quantity of step delays in the data-driven model; training the data-driven model through a one or more of a recurrent neural network (RNN), an autoregressive with non-linear input (ARX) model, and a nonlinear autoregressive exogenous (NARX) model; and determining whether a battery capacity estimation error is less than a threshold error. Upon determining that the battery capacity estimation error is greater than or equal to the threshold, the second control logic continues to define hidden layers and quantities of step delays in the data-driven model and continuing to train the data driven model through one or more of RNN, ARX and NARX, and upon determining that the battery capacity estimation error is less than the threshold error, the second control logic determines that the data-driven model design is complete and begins the third control logic.

In another aspect of the present disclosure, the third control logic further includes control logic for determining a charging status of the battery of the battery-operated device, and control logic that upon determining that the battery is currently being charged continuously monitors the charging status of the battery. The third control logic further includes control logic that upon determining that the battery is not currently being charged, causes the one or more sensors to begin measuring dynamic battery information during an operation or cycle of the battery-operated device, and control logic that, at a completion of the operation or cycle of the battery-operated device, causes the one or more sensors to stop measuring dynamic battery information, and store an operation or cycle time defining a duration of the operation or cycle.

In another aspect of the present disclosure, the third control logic further includes control logic for calculating bins of voltage (V), current (I), and temperature (T) of the battery according to the data-driven model design, and control logic for stacking the bins of voltage (V), current (I), and temperature (T) of the battery with the time duration for the operation or cycle, and the full original battery capacity. The third control logic further includes control logic for predicting a current battery capacity with the data-driven model. The current battery capacity is transmitted, by the controller via the HMI, to vehicle users, and to additional vehicle systems and control logics utilizing SoC information.

In another aspect of the present disclosure, the battery-operated device is a vehicle, and the system further includes one or more cloud-computing servers having a processor, a memory, and one or more I/O ports in communication with the sensors, the battery-operated device, and the HMI. The system transmits the data collected by the one or more sensors to the one or more cloud-computing servers, and performs the second control logic within the one or more cloud-computing servers,

In another aspect of the present disclosure, a method for efficient battery capacity estimation in a vehicle includes collecting, with one or more sensors disposed on a vehicle, real-time information about the vehicle, including real-time information about one or more batteries equipped to the vehicle. The method further includes transmitting, via a human-machine interface (HMI) disposed in the vehicle, information to vehicle occupants, and to vehicle subsystems. The method executes programmatic control logic including a battery capacity estimation (BCE) application stored in memory of a controller of the vehicle. The controllers of the vehicle each have a processor, a memory, and one or more input/output (I/O) ports. The I/O ports communicate with the one or more sensors, the vehicle, and the HMI. The BCE application further includes control logic including control logic for: performing local data collection from the one or more sensors of the vehicle, and for performing data conversion of the data collected by the one or more sensors, and training a data-driven BCE model with data converted from the data collected by the one or more sensors. The data conversion reduces a size of the data collected by the one or more sensors over time from a first size to a second size substantially smaller than the first size. The data conversion removes a time-dependency of the data from the one or more sensors. The BCE application further includes control logic for receiving the data-driven BCE model and for estimating a capacity of a battery of the vehicle, wherein upon determining an estimate of the capacity of the battery, the method generates a notification to the vehicle occupants, via the HMI, including the current battery capacity estimate. The method also shares the current battery capacity estimate with additional vehicle sub-systems utilizing accurate battery state-of-charge (SoC) estimations.

In another aspect of the present disclosure the method further includes: determining a charging status of the battery of the vehicle, upon determining that the battery is currently being charged, continuing to monitor the charging status of the battery, and upon determining that the battery is not currently being charged, causing the one or more sensors to begin measuring dynamic battery information during an operation or cycle of the vehicle. At a completion of the operation or cycle of the vehicle, the method causes the one or more sensors to stop measuring dynamic battery information, and storing an operation or cycle time defining a duration of the operation or cycle.

In another aspect of the present disclosure the dynamic battery information further includes a voltage (V), a current (I), and a temperature (T) of the battery.

In another aspect of the present disclosure the method further includes: determining whether an SoC of the battery is zero, and upon determining that the SoC of the battery is greater than zero, continuing to monitor the SoC of the battery until the SoC of the battery is equal to zero, and upon determining that the SoC of the battery is equal to zero, charging the battery and integrating current (I) until a state of charge of the battery is equal to 1. Upon determining that the state of charge of the battery is equal to one, the method generates a full original battery capacity based on integration of the current (I).

In another aspect of the present disclosure the method further includes: determining a quantity of data sets available for training, defining sizes of partitions for a voltage (V), a current (I), and a temperature (T) of the battery, and calculating bins of the voltage (V), current (I), and temperature (T) of the battery. The bins of the voltage (V), current (I), and temperature (T) of the battery are sized based on minimum and maximum values for each variable voltage (V), current (I), and temperature (T) of the battery, including control logic for obtaining voltage minimums and maximums (V_min, V_max) from battery specifications, current minimums and maximums (I_min, I_max) from battery performance data, temperature minimums and maximums (T_min, T_max) from battery operating condition information.

In another aspect of the present disclosure the method further includes: determining an optimal size of the bins by minimizing a performance index according to:

$$J = {\sum }_{k = 1}^{N} {{W}_{1} ( h ( {z}_{k} - {z}_{k - 1} ) )}^{2} + {W}_{2} N ; such that {z}_{0} = V\_min , {z}_{N} = V\_max for voltage ( V ) ; that {z}_{0} = I\_min , {z}_{N} = I\_max for current ( I ) , and that {z}_{0} = T\_min , {z}_{N} = T\_max for temperature ( T ) , {z}_{k} - {z}_{k - 1} > 0 ; N \leq {N}_{max} ∈ ℕ ;$$

where N is the number of bins, W is a weighting factor, and stacking the bins of voltage (V), current (I), and temperature (T) of the battery with the time duration for the operation or cycle, and the full original battery capacity.

In another aspect of the present disclosure the method further includes: augmenting new data to existing data, determining that data conversion is complete, and training a data-driven BCE model by: defining hidden layers and a quantity of step delays in the data-driven model, training the data-driven model through a one or more of a recurrent neural network (RNN), an autoregressive with non-linear input (ARX) model, and a nonlinear autoregressive exogenous (NARX) model, and determining whether a battery capacity estimation error is less than a threshold error. Upon determining that the battery capacity estimation error is greater than or equal to the threshold, the method continues to define hidden layers and quantities of step delays in the data-driven model and continues to train the data driven model through one or more of RNN, ARX and NARX. Upon determining that the battery capacity estimation error is less than the threshold error, the method determines that the data-driven model design is complete and beginning a current battery capacity estimation.

In another aspect of the present disclosure the method further includes: determining a charging status of the battery of the vehicle, and upon determining that the battery is currently being charged continuously monitoring the charging status of the battery. Upon determining that the battery is not currently being charged, the method causes the one or more sensors to begin measuring dynamic battery information during an operation or cycle of the vehicle, and at a completion of the operation or cycle of the vehicle, the method causes the one or more sensors to stop measuring dynamic battery information, and store an operation or cycle time defining a duration of the operation or cycle. The method further includes: calculating bins of voltage (V), current (I), and temperature (T) of the battery according to the data-driven model design, and stacking the bins of voltage (V), current (I), and temperature (T) of the battery with the time duration for the operation or cycle, and the full original battery capacity. The method further includes predicting a current battery capacity with the data-driven model, and transmitting the current battery capacity, by the controller via the HMI, to vehicle occupants, and sharing the current battery capacity estimate with additional vehicle sub-systems utilizing accurate battery state-of-charge (SoC) estimations.

In another aspect of the present disclosure, the method further includes: utilizing one or more cloud-computing servers each having a processor, memory, and I/O ports in communication with the sensors, the vehicle, and the HMI to execute a portion of the BCE application, including: receiving data collected by the one or more sensors within the one or more cloud-computing servers, and performing the data conversion within the one or more cloud-computing servers; and transmitting from the one or more cloud-computing servers, to the vehicle the data-driven BCE model.

In another aspect of the present disclosure a method for efficient battery capacity estimation in a vehicle includes: collecting, with one or more sensors disposed on a vehicle, real-time information about the vehicle, including real-time information about one or more batteries equipped to the vehicle, and transmitting, via a human-machine interface (HMI) disposed in the vehicle, information to vehicle occupants and to vehicle subsystems. The method further includes utilizing one or more cloud-computing servers, executing programmatic control logic including a battery capacity estimation (BCE) application stored in memory of a controller of the vehicle and within memory of controllers of the one or more cloud computing servers, the controllers of the vehicle and the one or more cloud computing servers each having a processor, a memory, and one or more input/output (I/O) ports, the I/O ports communicating with the one or more sensors, the one or more remote servers, the vehicle, and the HMI. The BCE application further includes control logic including: control logic for performing local data collection from the one or more sensors of the vehicle, including: determining a charging status of the battery of the vehicle. Upon determining that the battery is currently being charged, the method continues to monitor the charging status of the battery, and upon determining that the battery is not currently being charged, the method causes the one or more sensors to begin measuring dynamic battery information during an operation or cycle of the vehicle. At a completion of the operation or cycle of the vehicle, the method causes the one or more sensors to stop measuring dynamic battery information, and stores an operation or cycle time defining a duration of the operation or cycle, wherein the dynamic battery information further comprises: a voltage (V), a current (I), and a temperature (T) of the battery. The method further includes determining whether a state of charge (SoC) of the battery is zero, and upon determining that the SoC of the battery is greater than zero, continuing to monitor the SoC of the battery until the SoC of the battery is equal to zero, and upon determining that the SoC of the battery is equal to zero, charging the battery and integrating current (I) until a state of charge of the battery is equal to 1. Upon determining that the state of charge of the battery is equal to one, the method generates a full original battery capacity based on integration of the current (I). The method further includes transmitting the data collected by the one or more sensors to the one or more cloud-computing servers, and performs, within the one or more cloud-computing servers, data conversion of the data collected by the one or more sensors, and training a data-driven BCE model with data converted from the data collected by the one or more sensors, wherein the data conversion reduces a size of the data collected by the one or more sensors over time from a first size to a second size substantially smaller than the first size. The data conversion removes a time-dependency of the data from the one or more sensors. The data conversion and training further include determining a quantity of data sets available for training, defining sizes of partitions for a voltage (V), a current (I), and a temperature (T) of the battery, and calculating bins of the voltage (V), current (I), and temperature (T) of the battery. The bins of the voltage (V), current (I), and temperature (T) of the battery are sized based on minimum and maximum values for each variable voltage (V), current (I), and temperature (T) of the battery, including control logic for obtaining voltage minimums and maximums (V_min, V_max) from battery specifications, current minimums and maximums (I_min, I_max) from battery performance data, temperature minimums and maximums (T_min, T_max) from battery operating condition information. The method further includes determining an optimal size of the bins by minimizing a performance index according to:

$$J = {\sum }_{k = 1}^{N} {{W}_{1} ( h ( {z}_{k} - {z}_{k - 1} ) )}^{2} + {W}_{2} N ; such that {z}_{0} = V\_min , {z}_{N} = V\_max for voltage ( V ) ; that {z}_{0} = I\_min , {z}_{N} = I\_max for current ( I ) , and that {z}_{0} = T\_min , {z}_{N} = T\_max for temperature ( T ) , {z}_{k} - {z}_{k - 1} > 0 ; N \leq {N}_{max} ∈ ℕ ;$$

where N is the number of bins, W is a weighting factor; and stacking the bins of voltage (V), current (I), and temperature (T) of the battery with the time duration for the operation or cycle, and the full original battery capacity. The method further includes augmenting new data to existing data, determining that data conversion is complete, and training a data-driven BCE model. The method trains the data-driven BCE model by: defining hidden layers and a quantity of step delays in the data-driven model, utilizing one or more of a recurrent neural network (RNN), an autoregressive with non-linear input (ARX) model, and a nonlinear autoregressive exogenous (NARX) model, and determining whether a battery capacity estimation error is less than a threshold error. Upon determining that the battery capacity estimation error is greater than or equal to the threshold, the method continues to define hidden layers and quantities of step delays in the data-driven model and continues to train the data driven model through one or more of RNN, ARX and NARX. Upon determining that the battery capacity estimation error is less than the threshold error, the method determines that the data-driven model design is complete, and receives, from the cloud-computing server, the data-driven model and begins a current battery capacity estimation. The current battery capacity estimation includes: determining a charging status of the battery of the vehicle. Upon determining that the battery is currently being charged, the method continuously monitors the charging status of the battery, and upon determining that the battery is not currently being charged, the method causes the one or more sensors to begin measuring dynamic battery information during an operation or cycle of the vehicle. At a completion of the operation or cycle of the vehicle, the method causes the one or more sensors to stop measuring dynamic battery information, and store an operation or cycle time defining a duration of the operation or cycle. The method further includes calculating bins of voltage (V), current (I), and temperature (T) of the battery according to the data-driven model design, stacking the bins of voltage (V), current (I), and temperature (T) of the battery with the time duration for the operation or cycle, and the full original battery capacity, and predicting the current battery capacity with the data-driven model. Upon predicting the current battery capacity with the data driven model, the method generates a notification to the vehicle occupants, by the controller via the HMI, including the current battery capacity estimate, and shares the current battery capacity estimate with the additional vehicle sub-systems utilizing accurate battery SoC estimations.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a system for efficient battery capacity estimation according to an exemplary embodiment;

FIG. 2 is a partial schematic architecture diagram of a battery capacity estimation (BCE) application of the system for efficient battery capacity estimation of FIG. 1 according to an exemplary embodiment;

FIG. 3A is partial flowchart depicting a first portion of a method for efficient battery capacity estimation according to an exemplary embodiment; and

FIG. 3B is a partial flowchart depicting a second portion of the method for efficient battery capacity estimation of FIG. 3A according to an exemplary embodiment.

### DETAILED DESCRIPTION

The following description is merely exemplary in nature and is not intended to limit the present disclosure, application, or uses.

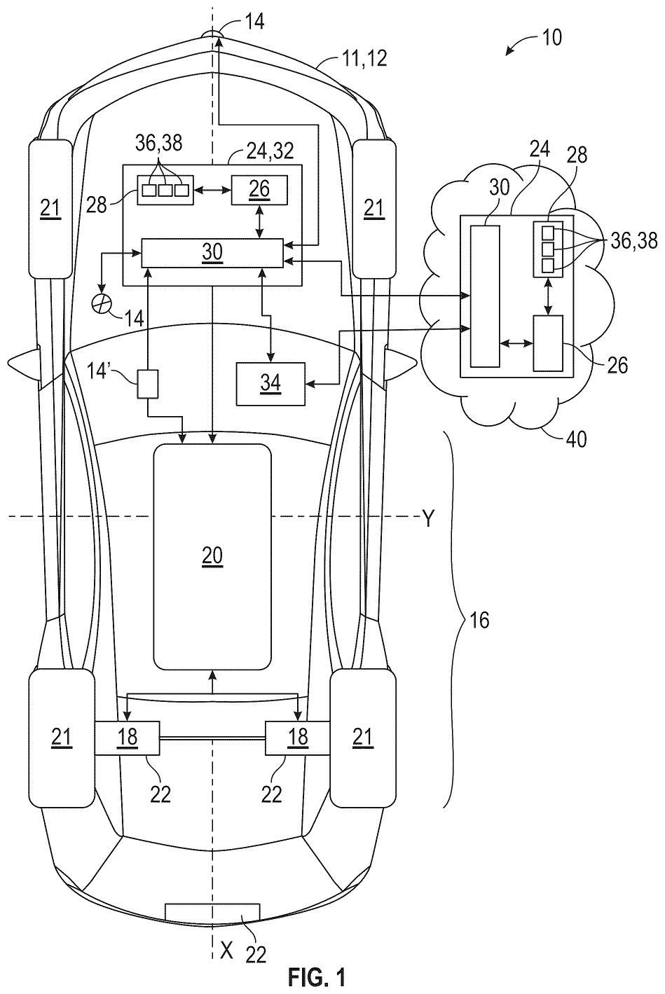

Referring to FIG. 1, a system 10 for efficient battery estimation is shown in schematic form. The system 10 includes one or more battery-operated devices 11. The battery-operated devices 11 be any of a wide variety of battery-operated items including but not limited to: cellular phones, computers, laptop computers, watches, smart watches, video game consoles and/or controllers, smoke detectors, carbon-dioxide detectors, carbon monoxide detectors, remote control devices such as remote controls for televisions or radio-controlled cars. In a non-limiting example, the system 10, as shown and described in relation to the figures of this disclosure, operates on a vehicle 12. The vehicle 12 shown is a passenger vehicle, however, it should be appreciated that the vehicle 12 may be any type of vehicle 12 without departing from the scope or intent of the present disclosure. In several examples, the vehicle 12 may be a passenger vehicle, a commercial vehicle, a truck, a van, a sport utility vehicle (SUV), a semi, a tractor trailer, a motorcycle, an electric bicycle, an aircraft such as: a plane, or a helicopter; a watercraft such as a boat, a ship; an amphibious vehicle, a tracked vehicle such as a tank, construction equipment such as: a backhoe, a front loader, a tractor, a steam-roller or the like.

The vehicle 12 is equipped with one or more sensors 14 detecting real-time information about the vehicle 12. The sensors 14 may include any of a wide variety of sensors 14 or sensor 14 types without departing from the scope or intent of the present disclosure. In several examples, the sensors 14 may include motion sensors 14 including but not limited to: microwave sensors, infrared sensors, ultrasonic sensors, vibration sensors, cameras each having a distinct field of view (FOV) in relation to other cameras or sensors 14. Additional sensors 14, such as inertial measurement units (IMUs), global positioning system (GPS) sensors, and the like, may also be equipped to the vehicle 12. IMUs measure movement, acceleration and the like in three or more degrees of freedom. GPS sensors communicate with a network of global positioning satellites (not specifically shown) to determine and report a position of the GPS sensor on the vehicle 12 on Earth. It will be appreciated that GPS sensors are commonly used in navigation applications, and to assist in determining locations of vehicles 12, packages carried by vehicles 12, and the like. Still other sensors 14 monitor, collect, and report information regarding the state of a propulsion system 16 of the vehicle 12.

The propulsion system 16 of the vehicle 12 includes at least one propulsion unit or motor 18, and a power source such as a battery 20. The battery 20 stores potential energy that may be released to the motor or motors 18, which subsequently convert the potential energy into kinetic energy that drives wheels 21 of the vehicle 12, thereby motivating or moving the vehicle 12. In a specific but non-limiting example, the system 10 includes one or more battery sensors 14′ capable of monitoring various aspects of the battery 20. The battery sensors 14′ may measure directly or indirectly a temperature (T) of the battery 20, a current or amperage (I) of the battery 20, a voltage (V) of the battery 20, and a capacity (C) of the battery. It will be appreciated that the battery 20 herein is being described as a singular “battery”, however, such singular batteries 20 are only intended to be a simple illustrative example. A quantity of batteries 20 equipped to or used within the system 10 of the present disclosure may vary substantially and without limitation without departing from the scope or intent of the present disclosure. In some additional non-limiting examples, the battery 20 may include a traction or high-voltage battery used for propulsion of the vehicle 12 while additional batteries may operate ancillary systems, such as climate control, lighting, and the like. In still further examples, the batteries 20 may include multiple traction or high-voltage batteries 20, multiple batteries supplying electrical energy for ancillary systems, and the like.

In further examples, the vehicle 12 includes one or more actuators 22. The actuators 22 may include in-plane actuators 22 such as all-wheel drive (AWD) actuators including electronically-controlled or electric all-wheel drive (eAWD) actuators, limited slip differentials (LSDs), including electronically-controlled or electric LSD (eLSD) systems. In-plane actuators 22 generate or modify force generation in X and/or Y directions at a contact patch between the wheels 21 of the vehicle 12 and a road surface. An eAWD system may transfer torque from a front to a rear of the vehicle 12 and/or from side-to-side of the vehicle 12. Likewise, an eLSD may transfer torque from side-to-side of the vehicle 12. In some examples, the eAWD and/or eLSD may directly alter or manage torque delivery from motors 18 and/or the eAWD and eLSD may act on a braking system of the vehicle 12 to adjust a quantity of torque delivered to the wheels 21 of the vehicle 12. Additional in-plane actuators 22 may include active steering or electronic power steering (EPS) systems at either or both of the front and rear axles of the vehicle 12. Active steering systems or EPS systems may actively adjust an angle of the wheels 21 relative to the longitudinal axis X of the vehicle 12.

In further examples, the vehicle 12 may include means of altering a normal force on each of the wheels 21 of the vehicle 12 via one or more out-of-plane actuators 22. The out-of-plane actuators 22 of the vehicle 12 may include any of a wide variety of actuators 22 capable of managing vertical movement of the vehicle 12. In several aspects, the out-of-plane actuators 22 may include active aerodynamic actuators, active suspension actuators, and the like. Active aerodynamic actuators may actively or passively alter an aerodynamic profile of the vehicle 12 via one or more active aerodynamic elements such as wings, spoilers, fans, or suction devices, actively-managed Venturi tunnels, splitters, or the like. Active suspension actuators 22 adjust suspension travel, spring rates, and damping characteristics of the vehicle 12 suspension. In some examples, the active suspension actuators 22 may include magnetorheological dampers, pneumatic dampers or springs, or other such electrically, hydraulically, or pneumatically adjusted dampers or springs without departing from the scope or intent of the present disclosure.

The terms “forward”, “rear”, “inner”, “inwardly”, “outer”, “outwardly”, “above”, and “below” are terms used relative to the orientation of the vehicle 12 as shown in the drawings of the present application. Thus, “forward” refers to a direction toward a front of a vehicle 12, “rearward” refers to a direction toward a rear of a vehicle 12. “Left” refers to a direction towards a left-hand side of the vehicle 12 relative to the front of the vehicle 12. Similarly, “right” refers to a direction towards a right-hand side of the vehicle 12 relative to the front of the vehicle 12. “Inner” and “inwardly” refers to a direction towards the interior of a vehicle 12, and “outer” and “outwardly” refers to a direction towards the exterior of a vehicle 12, “below” refers to a direction towards the bottom of the vehicle 12, and “above” refers to a direction towards a top of the vehicle 12. Further, the terms “top”, “overtop”, “bottom”, “side” and “above” are terms used relative to the orientation of the actuators, and the vehicle 12 more broadly shown in the drawings of the present application. Thus, while the orientation of actuators 22, or vehicle 12 may change with respect to a given use, these terms are intended to still apply relative to the orientation of the components of the system 10 and vehicle 12 components shown in the drawings.

The vehicle 12 also includes one or more controllers 24. The controllers 24 of the vehicle 12 are non-generalized, electronic control devices having a preprogrammed digital computer or processor 26, non-transitory computer readable medium or memory 28 used to store data such as control logic, software applications, instructions, computer code, data, lookup tables, etc., and a transceiver or input/output (I/O) ports 30. Computer readable medium or memory 28 includes any type of medium capable of being accessed by a computer, such as read only memory (ROM), random access memory (RAM), a hard disk drive, a compact disc (CD), a digital video disc (DVD), or any other type of memory 28. A “non-transitory” computer readable memory 28 excludes wired, wireless, optical, or other communication links that transport transitory electrical or other signals. A non-transitory computer readable memory 28 includes media where data can be permanently stored and media where data can be stored and later overwritten, such as a rewritable optical disc or an erasable memory device. Computer code includes any type of program code, including source code, object code, and executable code. The processor 26 is configured to execute the code or instructions.

The controller 24 may be a dedicated Wi-Fi controller, an engine or motor 18 control module, a transmission control module, a body control module, an infotainment control module 32 in electronic communication with a human-machine interface (HMI) 34 of the vehicle 12, or the like. In several aspects, the controllers 24 may be stand-alone devices within the vehicle 12 or multiple control modules or multiple virtual control modules may reside within a single physical controller 24 without departing from the scope or intent of the present disclosure. The I/O ports 30 are configured to communicate via wired connections, and/or via wireless connections utilizing Wi-Fi protocols under IEEE 802.11x, cellular protocols, satellite communications protocols, or the like. The HMI 34 of the vehicle 12 may take a variety of forms without departing from the scope or intent of the present disclosure. In a non-limiting example, the HMI 34 defines an interactive display or screen disposed within the passenger compartment of the vehicle and capable of transmitting audiovisual information and/or haptic feedback to vehicle 12 operators or users. In additional non-limiting examples, the HMI 34 may be an infotainment display, a heads-up display, a driver information display, a passenger information display, a third-party device such as a cellular device, smartphone, laptop computer, tablet computer, or the like without departing from the scope or intent of the present disclosure.

The controller 24 further includes one or more applications 36. An application 36 is a software program configured to perform a specific function or set of functions. The application 36 may include one or more computer programs, software components, sets of instructions, procedures, functions, objects, classes, instances, related data, or a portion thereof adapted for implementation in a suitable computer readable program code. The applications 36 may be stored within the memory 28 or in additional or separate memory 28. Examples of the applications 36 include audio or video streaming services, games, browsers, social media applications, vehicle motion control (VMC) applications, and, as in the vehicle 12 of the present disclosure, a vehicle battery capacity estimation (BCE) application 38.

In some examples, the system 10 may further include a back office or cloud-computing server 40, and may include additional infrastructure, such as one or more cellular towers (not specifically shown), cameras mounted to infrastructure such as buildings, traffic signals, and the like, or sensors 14 mounted to or otherwise disposed in infrastructure such as electric vehicle (EV) chargers, and the like. The vehicle's 12 sensors 14 are in electronic communication the controller 24 and may further be in electronic communication either directly or indirectly with the cloud computing server 40 without departing from the scope or intent of the present disclosure.

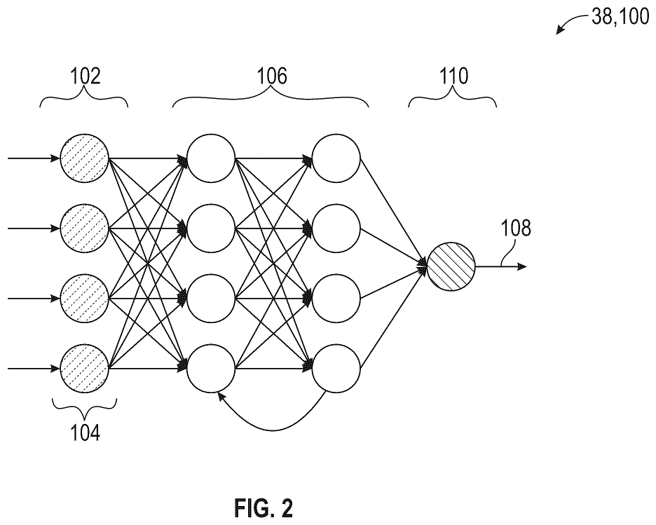

Turning now to FIG. 2 and with continuing reference to FIG. 1, a recurrent neural network (RNN) 100 of the BCE application 38 is shown in further detail in schematic form. The BCE application 38 obtains live battery 20 data from the battery sensors 14′ of the vehicle 12. The live battery data 20 is fed into an input layer 102 of the RNN 100. The live battery 20 data includes a voltage (V) of the battery 20, a current (I) of the battery 20, a temperature (T) of the battery 20 over a specified quantity or duration of time defining a snapshot 104 of the battery's 20 use. It will be appreciated that the time period defining the snapshot 104 may vary. The snapshot 104 duration may be any duration from a certain voltage (V), current (I), or state-of-charge (SoC) to another voltage (V), current (I), or SoC. A series of such snapshots 104 is then fed into a plurality of hidden layers 106 of the RNN 100 to train a battery 20 capacity estimation model. In some additional non-limiting examples, the RNN 100 may utilize an autoregressive with non-linear input (ARX) model or a nonlinear autoregressive exogenous model (NARX) model to train the battery 20 capacity estimation model. Once the RNN 100 is trained, the RNN 100 outputs a battery capacity estimate 108 within an output layer 110 of the RNN 100. The battery 20 capacity estimate 108 may be stored internally on the controller 24, transmitted to the cloud computing server 40, and/or transmitted to and displayed upon or otherwise transmitted via the HMI 34 to the driver, operator, or user of the vehicle 12. That is, the battery capacity estimate 108 may be sent as a notification to the vehicle 12 operator, driver, or user, and continuously and/or periodically updated as revisions to the battery capacity estimate 108 are generated by the system 10 and BCE application 38.

In order to streamline data processing within the RNN 100, and to reduce computational effort and improve computational efficiency within the controller 24 relative to a pure time-series analysis, the system 10 of the present disclosure generates a series of snapshots 104 of the live battery 20 data. Specifically, the BCE application 38 includes control logic that captures data over the period of time defining the snapshot 104, and aggregates the snapshot 104 data. In an example, rather than obtaining pure time-series data in which 115,200 bytes of data would be obtained over one hour of elapsed time (i.e. 8 bytes×4 variables×3600 seconds), the BCE application 38 utilizes snapshots in which voltage (V) is divided into five bins (k), current (I) is divided into ten bins (k), temperature (T) is divided into six bins (k), and the time duration is given a single bin (k). Accordingly, a total of twenty-two (22) variables (i.e. voltage (5)+current (10)+temperature (6)+time duration (1)=22) is available for each time-series data. Battery 20 capacity and the twenty-two variables noted above have the same time-scale. Thus, rather than requiring 115,200 bytes of data, the BCE application 38 allows for 184 bytes of data to be used per snapshot [i.e. 8 bytes×(22+1 variables)]. Because of the dramatically reduced quantity of data for the same quantity of clock time, the BCE application 38 may operate on lightweight computing hardware, and with decreased energy, thermal, and computational hardware and storage requirements, thereby improving the speed and functionality of the system 10 without adding to the underlying hardware complexity.

Determining the appropriate quantity of bins (k) in the system 10 aids in providing accurate battery 20 capacity estimation. In some examples, the quantity of bins (k) is determined using a physics-based model. However, a data-driven model offers several advantages. Optimal sizing of bins (k) for variables is determined based on minimum and maximum values. The minimum and maximum values may be obtained from a variety of sources including, obtaining voltage minimums and maximums (V_min, V_max) from battery 20 specifications, current minimums and maximums (I_min, I_max) from battery 20 performance data, temperature minimums and maximums (T_min, T_max) from battery 20 operating condition information, and the like. From the minimum and maximum values, the number of bins (N), and a weighting factor (W), the optimal size of the bins for each of the variables [i.e. for each of Voltage (V), current (I), and temperature (T)] may then be determined according to: zₖ(k=1, . . . , N) and N that minimize the following performance index J,

$$J = {\sum }_{k = 1}^{N} {{W}_{1} ( h ( {z}_{k} - {z}_{k - 1} ) )}^{2} + {W}_{2} N ;$$

$$such that {z}_{0} = V\_min , {z}_{N} = V\_max for voltage ( V ) ; that {z}_{0} = I\_min , {z}_{N} = I\_max for current ( I ) , and that {z}_{0} = T\_min , {z}_{N} = T\_max for temperature ( T ) .$$

$${z}_{k} - {z}_{k - 1} > 0 ;$$

$$N \leq {N}_{max} ∈ ℕ .$$

In some non-limiting examples, when measured voltage (V), current (I), or temperature (T) are large, the bins are relatively narrow, or short in duration by comparison to when measured voltage (V), current (I), or temperature (T) are small, as when the measured voltage (V), current (I), or temperature (T) are small, the system 10 and BCE application 38 widen, combine, or otherwise capture measurements of voltage (V), current (I), or temperature (T) over longer durations. However, it will be appreciated that in general, the system 10 and BCE application 38 attempt to maximize the size of each of the bins, as the larger the bins are, the better the computational efficiency that results.

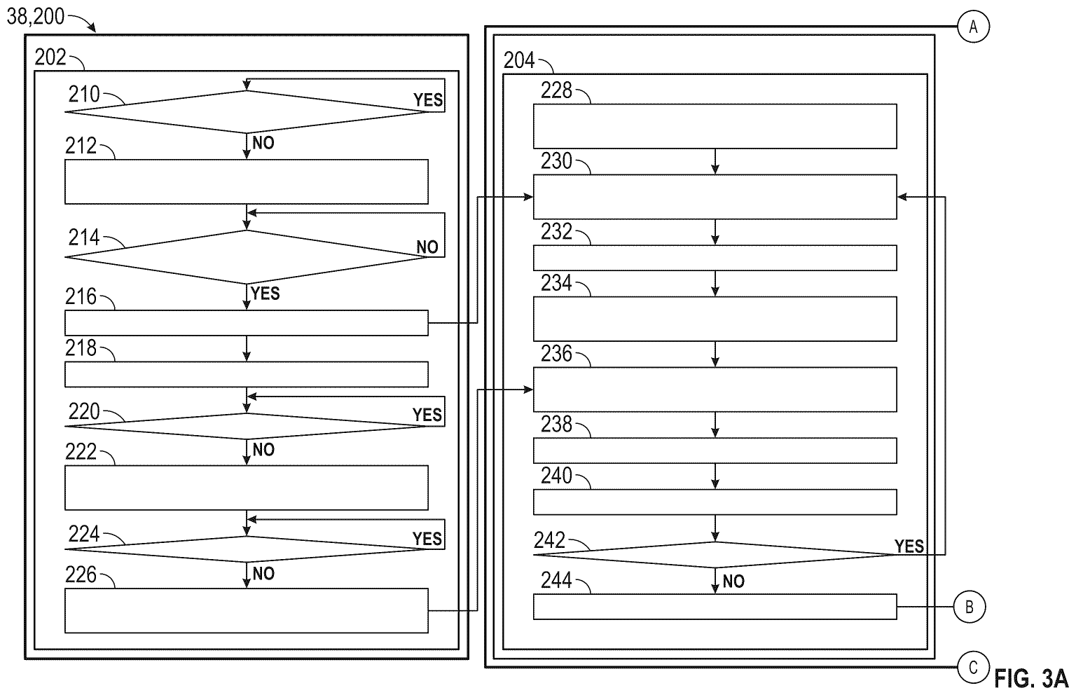

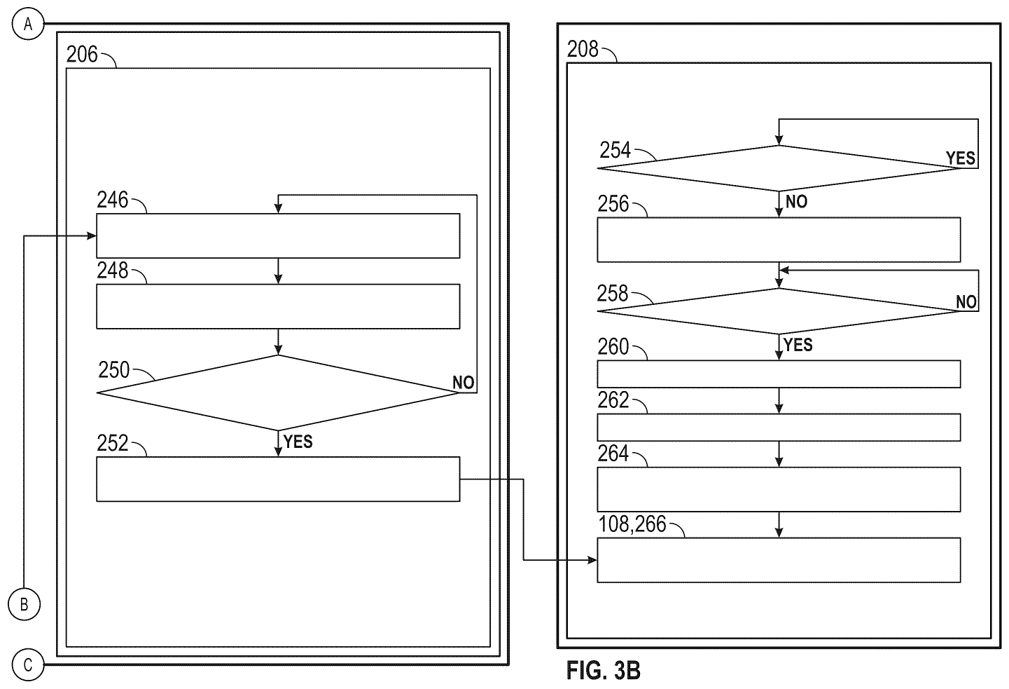

Turning now to FIGS. 3A and 3B, and with continuing reference to FIGS. 1 and 2, a flowchart 200 depicting a method of using the BCE application 38, is shown in further detail. The method 200 begins within block 202 which defines a data collection phase of the method 200. In several aspects, the data collection phase 202 of the method 200 is carried out by the vehicle 12 manufacturer, by a fleet manager for a fleet of vehicles 12 utilizing the system 10 of the present disclosure, or by volunteer vehicle 12 operators or users. Data collected during the data collection phase 202 of the method 200 is transmitted to the cloud-computing server 40, where a data conversion phase 204 and an RNN 100 model training phase 206 are carried out. In several aspects, the data conversion phase 204 and RNN 100 model training phase 206 may be carried out in the cloud-computing server 40, in pre-production of the vehicle 12, or the like without departing from the scope or intent of the present disclosure. From the cloud-computing server 40, individual vehicles 12 carry out a battery 20 capacity estimation phase 208 of the method 200 within the on-board controllers 24 of the vehicle.

Referring once more to the data collection phase 202 of the method 200, the method 200 determines whether the vehicle 12 is currently being charged at block 210 In several examples, the vehicle 12 is an EV. When the EV vehicle 12 is being charged, recharged, or the like via wired or wireless charging techniques the method 200 periodically and/or continuously re-checks to determine whether the vehicle 12 is still being charged at block 210. Upon determining at block 204 that the vehicle 12 is no longer being charged, the method 200 proceeds to block 212. At block 212, the vehicle 12 is operated either by a vehicle 12 operator, a user, autonomously, semi-autonomously, or entirely manually. While the vehicle 12 is in operation, the sensors 14, and specifically the battery sensors 14′ of the vehicle 12 measure at least voltage (V), current (I), and temperature (T) of the battery 20.

The method 200 subsequently proceeds to block 214, where the BCE application 38 determines whether an operational cycle of the vehicle 12 is complete. Upon determining that the cycle is incomplete, the method 200 periodically and/or continuously rechecks to determine whether the operational cycle of the vehicle 12 is complete at block 214. Once the operational cycle has been completed, the BCE application 38 and method 200 proceed to block 216, where the sensors 14 and specifically battery sensors 14′ are commanded to stop measuring voltage (V), current (I), and temperature (T) of the battery 20, and to store the voltage (V), current (I), and temperature (T) of the battery 20, as well as an operational time or usage time of the vehicle 12. From block 216, the stored voltage (V), current (I), temperature (T), and operational time or usage time data are sent both to the data cloud computing server 40, and to block 218.

At block 218, the method 200 and BCE application 38 causes the battery 20 or a sub-component thereof, such as a battery cell, a battery module, or the like, to discharge while the vehicle 12 is in use. The method 200 proceeds to block 220, where the BCE application 38 determines whether a state of charge (SoC) of the battery 20 is greater than zero. When, at block 220, the SoC is greater than zero the method 200 and BCE application 38 periodically and/or continuously utilize the battery sensors 14′ to monitor the SoC of the battery 20. Upon determining at block 220 that the SoC of the battery is equal to zero, the method proceeds to block 222. In several aspects, an SoC of zero indicates that the battery 20, or components thereof are fully discharged.

At block 222, the method 200 and BCE application 38 cause the battery 20 to charge, including charging sub-components of the battery 20, such as individual battery cells, battery modules, and the like. The current (I) applied to the battery 20 is integrated to assist in determining the SoC of the battery 20 as the battery 20 is charged. From block 222, the method 200 proceeds to block 224 where the method 200 and BCE application 38 once more monitors the SoC of the battery 20 continuously and/or periodically through the battery sensors 14′.

At block 224, upon determining that the SoC of the battery 20 is less than one (1), the method 200 and BCE application 38 periodically and continuously monitors the SoC of the battery 20. In several aspects, an SoC of one (1) indicates a fully-charged battery 20 or component thereof. Upon determining that the SoC of the battery 20 is equal to one (1), the method proceeds to block 226. At block 226, the method 200 and BCE application 38 generate a full original battery 20 capacity based on integration of the current (I) applied to the battery 20.

Referring once more to block 216, the stored voltage (V), current (I), temperature (T), and operational time or usage time data are received within the cloud computing server 40 for data conversion 204. Specifically, the BCE application 38 checks a quantity of data sets (N) available for training the RNN 100 for M<1 at block 228. At block 230, the stored, and operational time or usage time data from block 216, and the quantity of data sets (N) from block 228 are received. At block 230, the method 200 and BCE application 38 define sizes of partitions for voltage (V), current (I), temperature (T) for the Mth data. At block 232, the method 200 and BCE application 38 calculate the bins of voltage (V), current (I), temperature (T). At block 234, the bins of voltage (V), current (I), temperature (T) are stacked with the time duration of vehicle 12 usage, and at block 236, the bins of voltage (V), current (I), temperature (T) and time duration are stacked with the full original battery 20 capacity originally calculated at block 226 in the data collection phase 202.

At block 238, the method 200 and BCE application 38 augment Mth data to existing data and transmit the augmented Mth data to train the RNN 100 in the RNN model training phase 206, as well as forwarding the augmented Mth data to block 240. At block 240, the Mth data is updated at a subsequent time step such that M<M+1, and then at block 242, the method 200 and BCE application 38 determines whether M is less than or equal to N. The Mth data set is one of N data sets extending from 1 to N in a loop. M is increased gradually at block 240 up to a final value of N. When M is less than or equal to N, the method 200 and BCE application 38 return to block 230, whereas when M is greater than N, the method 200 and BCE application 38 proceed to block 244, where the data conversion phase 204 is completed.

The RNN model training phase 206 begins at block 246 where hidden layers and a quantity of step delays for the data-driven model utilized by the BCE application 38 are defined. In addition, block 246 receives the augmented data from block 244. At block 248, the hidden layers, quantity of step delays, and the augmented data from block 246 is used to train the data-driven model by utilizing RNN 100, ARX, NARX, or the like. From block 248 the method 200 and BCE application 38 proceed to block 250 where a battery 20 capacity estimation error is compared to a threshold value. In several aspects, the threshold is a user or manufacturer-defined variable that defines an accuracy of the battery 20 capacity estimation. In some non-limiting examples, the threshold may be a battery 20 capacity estimation error of 1%, 2%, 5%, or the like. Upon determining at block 250 that the battery 20 capacity estimation error is greater than or equal to the threshold value, the method 200 and BCE application 38 return to block 246. However, upon determining at block 250 that the battery 20 capacity estimation error is less than the threshold value, the method 200 and BCE application 38 proceed to block 252 where the method 200 and BCE application 38 define that the data-driven model design for battery 20 capacity estimation is complete. The method 200 and BCE application 38 subsequently proceed from block 252 to the capacity estimation phase 208 which begins at block 254.

At block 254, the method 200 and BCE application 38 determine whether the vehicle 12 is currently charging. Upon determining that the vehicle 12 is charging currently, the method 200 and BCE application 38 periodically and/or continuously monitors the vehicle 12, and more specifically, the battery 20 to determine when the battery 20 is no longer being charged. Upon finding at block 254 that the vehicle 12 battery 20 is not being charged, the method 200 and BCE application 38 proceed to block 256. At block 256, the method 200 and BCE application 38 operate the vehicle 12 or cycle, and begin measuring the voltage (V), current (I), and temperature (T) of the battery 20. The method 200 and BCE application 38 then proceed from block 256 to block 258 where the method 200 and BCE application 38 determine whether the operation or cycle is complete. Upon determining that the vehicle is continuing to operate or that the cycle is still incomplete, the method 200 and BCE application 38 periodically and/or continuously monitor the vehicle 12 to determine whether and when the operation or cycle has completed at block 258. However, once at block 258 the operation or cycle is determined to have been completed, the method 200 and BCE application 38 proceed to block 260. At block 260, the method 200 and BCE application 38 cease measuring the voltage (V), current (I), and temperature (T), and store the time of operation, or the cycle time. Subsequently, at block 262, the method 200 and BCE application 38 calculate the bins of the voltage (V), current (I), and temperature (T) for the battery 20. At block 264, the bins of the voltage (V), current (I), and temperature (T) are stacked with the duration of time for the operation or cycle time. Finally at block 266, the method 200 and BCE application 38, the stacked bins of the voltage (V), current (I), and temperature (T) from block 264 and the completed data-driven model design from block 252 to generate a predicted battery 20 capacity, or battery 20 capacity estimate 108. As noted previously, the battery 20 capacity estimate 108 may be stored internally on the controller 24, transmitted to the cloud computing server 40, and/or transmitted to and displayed upon or otherwise transmitted via the HMI 34 to the driver, operator, or user of the vehicle 12. That is, the battery capacity estimate 108 may be sent as a notification to the vehicle 12 operator, driver, or user, and continuously and/or periodically updated as revisions to the battery capacity estimate 108 are generated by the system 10, method 200, and BCE application 38.

It will be appreciated that while the method 200 and BCE application 38 are described hereinabove in relation to a vehicle 12, and specifically in relation to an EV, the exemplary vehicle 12 or EV is merely non-limiting embodiment. The concepts disclosed herein with respect to the system 10, method 200, and BCE application 38 may operate effectively and efficiently on other types of battery-operated devices 11 including but not limited to: cellular phones, computers, laptop computers, watches, smart watches, video game consoles and/or controllers, smoke detectors, carbon-dioxide detectors, carbon monoxide detectors, remote control devices such as remote controls for televisions or radio-controlled cars, and the like without departing from the scope or intent of the present disclosure.

Battery 20 capacity estimation is an important factor in battery state estimation (BSE). However, battery 20 capacity estimation is challenging, because while Coulomb counting is known in the art, to make an accurate assessment of the capacity of a battery 20 using Coulomb counting, the battery 20 needs to be fully discharged regularly. In many use cases, such as in vehicles 12, cellular phones, computers, laptop computers, and a wide variety of other battery 20 powered devices, fully discharging the battery 20 may frustrate the purpose of the battery 20 operated devices, and reduce users abilities to utilize the battery 20 powered devices effectively. In addition, fully discharging the battery 20 can be detrimental to battery 20 health. Furthermore, using Coulomb counting methods and systems is made more accurate by using different time-scales to see dynamic changes among measured signals. Measuring and storing voltage (V), current (I), and temperature (T) data in the short term (i.e. milliseconds to minutes), and measuring capacity over the long term (i.e. months to years), can require substantial data storage space and computational resources.

Accordingly, the system 10, method 200, and BCE application 38 of the present disclosure offer many advantages. These include the ability to produce high accuracy battery 20 capacity estimates while consuming minimal computational resources through data conversion of time-series data to a series of snapshots and resolving different time-scales among the collected data. The collected data is then processed via the data-driven model utilizing RNN, ARX, NARX, or the like, which allows the system 10, method 200, and BCE application 38 to effectively handle event-based data to accurately estimate battery 20 capacity, and provide such information via the HMI 34 to vehicle 12 operators, users, and to vehicle 12 manufacturers, service departments, and the like, while utilizing existing hardware, being portable and retrofittable, maintaining or reducing manufacturing complexity, improving efficiency and accuracy of battery capacity estimations, reducing computational efforts and computational resource utilization, and providing redundancy, prediction reliability, and increasing users' abilities to effectively utilize battery operated devices utilizing the system 10 and method 200 of the present disclosure while reducing range anxiety among users of vehicles 12 utilizing the system 10, method 200, and BCE application 38 of the present disclosure.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A system for efficient battery capacity estimation in a battery-operated device, the system comprising:
a battery-operated device having one or more batteries;
one or more sensors disposed on the battery-operated device and collecting real-time information about the battery-operated device;
a human-machine interface (HMI) disposed in the battery-operated device and transmitting information to battery-operated device users;
the battery-operated device has a controller with a processor, a memory, and one or more input/output (I/O) ports, the I/O ports communicating with the one or more sensors, the battery-operated device, and the HMI; the processor executing programmatic control logic stored in the memory; the programmatic control logic including a battery capacity estimation (BCE) application, the BCE application comprising:
a first control logic for performing local data collection from the one or more sensors of the battery-operated device;
a second control logic for data conversion of the data collected by the one or more sensors, and training a data-driven BCE model with data converted from the data collected by the one or more sensors, wherein the data conversion reduces a size of the data collected by the one or more sensors over time from a first size to a second size substantially smaller than the first size, wherein the data conversion removes a time-dependency of the data from the one or more sensors; and
a third control logic for estimating a capacity of a battery of the battery-operated device, wherein upon determining an estimate of the capacity of the battery, the system generates a notification to the battery-operated device users, via the HMI, including the current battery capacity estimate, and shares the current battery capacity estimate with additional battery-operated device sub-systems utilizing accurate battery state-of-charge (SoC) estimations.

2. The system of claim 1, wherein the first control logic further comprises:
control logic for determining a charging status of the battery of the battery-operated device;
control logic that upon determining that the battery is currently being charged continuing to monitor the charging status of the battery;
control logic that upon determining that the battery is not currently being charged, causes the one or more sensors to begin measuring dynamic battery information during an operation or cycle of the battery-operated device; and
control logic that at a completion of the operation or cycle of the battery-operated device, causes the one or more sensors to stop measuring dynamic battery information, and storing an operation or cycle time defining a duration of the operation or cycle.

3. The system of claim 2, wherein the dynamic battery information further comprises:
a voltage (V), a current (I), and a temperature (T) of the battery.

4. The system of claim 3, wherein the first control logic further comprises:
control logic for determining whether the SoC of the battery is zero; and
control logic that upon determining that the SoC of the battery is greater than zero, continues to monitor the SoC of the battery until the SoC of the battery is equal to zero;
control logic that upon determining that the SoC of the battery is equal to zero, charges the battery and integrating current (I) until a state of charge of the battery is equal to 1; and
control logic that upon determining that the state of charge of the battery is equal to one, generates a full original battery capacity based on integration of the current (I).

5. The system of claim 4, wherein the second control logic further comprises:
control logic for determining a quantity of data sets available for training;
control logic for defining sizes of partitions for a voltage (V), a current (I), and a temperature (T) of the battery; and
control logic for calculating bins of the voltage (V), current (I), and temperature (T) of the battery, wherein the bins of the voltage (V), current (I), and temperature (T) of the battery are sized based on minimum and maximum values for each variable voltage (V), current (I), and temperature (T) of the battery, including control logic for obtaining voltage minimums and maximums (V_min, V_max) from battery specifications, current minimums and maximums (I_min, I_max) from battery performance data, temperature minimums and maximums (T_min, T_max) from battery operating condition information.

6. The system of claim 5, wherein the second control logic further comprises:
control logic for determining an optimal size of the bins by minimizing a performance index according to:
$$J = {\sum }_{k = 1}^{N} {{W}_{1} ( h ( {z}_{k} - {z}_{k - 1} ) )}^{2} + {W}_{2} N ; such that {z}_{0} = {V}_{min} , {z}_{N} = {V}_{max} for voltage ( V ) ; that {z}_{0} = {I}_{min} , {z}_{N} = {I}_{max} for current ( I ) , and that {z}_{0} = {T}_{min} , {z}_{N} = {T}_{max} for temperature ( T ) , {z}_{k} - {z}_{k - 1} > 0 ; N \leq {N}_{max} ∈ ℕ ;$$
where N is the number of bins, W is a weighting factor; and
control logic for stacking the bins of voltage (V), current (I), and temperature (T) of the battery with the time duration for the operation or cycle, and the full original battery capacity.

7. The system of claim 6, wherein the second control logic further comprises:
control logic for augmenting new data to existing data;
control logic for determining that data conversion is complete; and
control logic for training a data-driven BCE model by:
defining hidden layers and a quantity of step delays in the data-driven model;
training the data-driven model through a one or more of a recurrent neural network (RNN), an autoregressive with non-linear input (ARX) model, and a nonlinear autoregressive exogenous (NARX) model;
determining whether a battery capacity estimation error is less than a threshold error;
wherein upon determining that the battery capacity estimation error is greater than or equal to the threshold, continuing to define hidden layers and quantities of step delays in the data-driven model and continuing to train the data driven model through one or more of RNN, ARX and NARX; and
wherein upon determining that the battery capacity estimation error is less than the threshold error, determining that the data-driven model design is complete and beginning the third control logic.

8. The system of claim 7, wherein the third control logic further comprises:
control logic for determining a charging status of the battery of the battery-operated device;
control logic that upon determining that the battery is currently being charged continuously monitors the charging status of the battery;
control logic that upon determining that the battery is not currently being charged, causes the one or more sensors to begin measuring dynamic battery information during an operation or cycle of the battery-operated device; and
control logic that at a completion of the operation or cycle of the battery-operated device, causes the one or more sensors to stop measuring dynamic battery information, and store an operation or cycle time defining a duration of the operation or cycle.

9. The system of claim 8, wherein the third control logic further comprises:
control logic for calculating bins of voltage (V), current (I), and temperature (T) of the battery according to the data-driven model design; and
control logic for stacking the bins of voltage (V), current (I), and temperature (T) of the battery with the time duration for the operation or cycle, and the full original battery capacity; and
control logic for predicting a current battery capacity with the data-driven model, wherein the current battery capacity is transmitted, by the controller via the HMI, to vehicle users, and to additional vehicle systems and control logics utilizing SoC information.

10. The system of claim 9, wherein the battery-operated device is a vehicle; and wherein the second control logic is performed within one or more cloud-computing servers in wireless communication with the I/O ports of the battery-operated device, each of the one or more cloud-computing servers having a processor, a memory, and I/O ports in communication with the sensors, the vehicle, and the HMI.

11. A method for efficient battery capacity estimation in a vehicle, the method comprising:
collecting, with one or more sensors disposed on a vehicle, real-time information about the vehicle, including real-time information about one or more batteries equipped to the vehicle;
transmitting, via a human-machine interface (HMI) disposed in the vehicle, information to vehicle occupants, and to vehicle subsystems;
executing programmatic control logic including a battery capacity estimation (BCE) application stored in memory of a controller of the vehicle, the controllers of the vehicle each having a processor, a memory, and one or more input/output (I/O) ports, the I/O ports communicating with the one or more sensors, the vehicle, and the HMI, wherein the BCE application further includes control logic comprising:
performing local data collection from the one or more sensors of the vehicle;
performing data conversion of the data collected by the one or more sensors, and training a data-driven BCE model with data converted from the data collected by the one or more sensors, wherein the data conversion reduces a size of the data collected by the one or more sensors over time from a first size to a second size substantially smaller than the first size, wherein the data conversion removes a time-dependency of the data from the one or more sensors; and
estimating a capacity of a battery of the vehicle from the data-driven BCE model, wherein upon determining an estimate of the capacity of the battery, the method generates a notification to the vehicle occupants, via the HMI, including the current battery capacity estimate, wherein the method also shares the current battery capacity estimate with additional vehicle sub-systems utilizing accurate battery state-of-charge (SoC) estimations.

12. The method of claim 10, further comprising:
determining a charging status of the battery of the vehicle;
upon determining that the battery is currently being charged, continuing to monitor the charging status of the battery; and
upon determining that the battery is not currently being charged, causing the one or more sensors to begin measuring dynamic battery information during an operation or cycle of the vehicle; and
at a completion of the operation or cycle of the vehicle, causing the one or more sensors to stop measuring dynamic battery information, and storing an operation or cycle time defining a duration of the operation or cycle.

13. The method of claim 12, wherein the dynamic battery information further comprises:
a voltage (V), a current (I), and a temperature (T) of the battery.

14. The method of claim 13, further comprising:
determining whether an SoC of the battery is zero; and
upon determining that the SoC of the battery is greater than zero, continuing to monitor the SoC of the battery until the SoC of the battery is equal to zero; and
upon determining that the SoC of the battery is equal to zero, charging the battery and integrating current (I) until a state of charge of the battery is equal to 1; and
upon determining that the state of charge of the battery is equal to one, generating a full original battery capacity based on integration of the current (I).

15. The method of claim 14 further comprising:
determining a quantity of data sets available for training;
defining sizes of partitions for a voltage (V), a current (I), and a temperature (T) of the battery; and
calculating bins of the voltage (V), current (I), and temperature (T) of the battery, wherein the bins of the voltage (V), current (I), and temperature (T) of the battery are sized based on minimum and maximum values for each variable voltage (V), current (I), and temperature (T) of the battery, including control logic for obtaining voltage minimums and maximums (V_min, V_max) from battery specifications, current minimums and maximums (I_min, I_max) from battery performance data, temperature minimums and maximums (T_min, T_max) from battery operating condition information.

16. The method of claim 5, further comprising:
determining an optimal size of the bins by minimizing a performance index according to:
$$J = {\sum }_{k = 1}^{N} {{W}_{1} ( h ( {z}_{k} - {z}_{k - 1} ) )}^{2} + {W}_{2} N ; such that {z}_{0} = {V}_{min} , {z}_{N} = {V}_{max} for voltage ( V ) ; that {z}_{0} = {I}_{min} , {z}_{N} = {I}_{max} for current ( I ) , and that {z}_{0} = {T}_{min} , {z}_{N} = {T}_{max} for temperature ( T ) , {z}_{k} - {z}_{k - 1} > 0 ; N \leq {N}_{max} ∈ ℕ ;$$
where N is the number of bins, W is a weighting factor; and
stacking the bins of voltage (V), current (I), and temperature (T) of the battery with the time duration for the operation or cycle, and the full original battery capacity.

17. The method of claim 16, further comprising:
augmenting new data to existing data;
determining that data conversion is complete; and
training a data-driven BCE model by:
defining hidden layers and a quantity of step delays in the data-driven model;
training the data-driven model through a one or more of a recurrent neural network (RNN), an autoregressive with non-linear input (ARX) model, and a nonlinear autoregressive exogenous (NARX) model; and
determining whether a battery capacity estimation error is less than a threshold error; and
wherein upon determining that the battery capacity estimation error is greater than or equal to the threshold, continuing to define hidden layers and quantities of step delays in the data-driven model and continuing to train the data driven model through one or more of RNN, ARX and NARX; and
wherein upon determining that the battery capacity estimation error is less than the threshold error, determining that the data-driven model design is complete and beginning a current battery capacity estimation.

18. The method of claim 17, further comprising:
determining a charging status of the battery of the vehicle;
upon determining that the battery is currently being charged continuously monitoring the charging status of the battery;
upon determining that the battery is not currently being charged, causing the one or more sensors to begin measuring dynamic battery information during an operation or cycle of the vehicle; and
at a completion of the operation or cycle of the vehicle, causing the one or more sensors to stop measuring dynamic battery information, and store an operation or cycle time defining a duration of the operation or cycle;
calculating bins of voltage (V), current (I), and temperature (T) of the battery according to the data-driven model design;
stacking the bins of voltage (V), current (I), and temperature (T) of the battery with the time duration for the operation or cycle, and the full original battery capacity;
predicting a current battery capacity with the data-driven model; and
transmitting the current battery capacity, by the controller via the HMI, to vehicle occupants, and sharing the current battery capacity estimate with additional vehicle sub-systems utilizing accurate battery state-of-charge (SoC) estimations.

19. The method of claim 18, further comprising:
utilizing one or more cloud-computing servers each having a processor, memory, and I/O ports in communication with the sensors, the vehicle, and the HMI to execute a portion of the BCE application, including:
receiving data collected by the one or more sensors within the one or more cloud-computing servers, and performing the data conversion within the one or more cloud-computing servers; and
transmitting from the one or more cloud-computing servers, to the vehicle the data-driven BCE model.

20. A method for efficient battery capacity estimation in a vehicle, the method comprising:
collecting, with one or more sensors disposed on a vehicle, real-time information about the vehicle, including real-time information about one or more batteries equipped to the vehicle;
transmitting, via a human-machine interface (HMI) disposed in the vehicle, information to vehicle occupants and to vehicle subsystems;
utilizing one or more cloud-computing servers;
executing programmatic control logic including a battery capacity estimation (BCE) application stored in memory of a controller of the vehicle and within memory of controllers of the one or more cloud computing servers, the controllers of the vehicle and the one or more cloud computing servers each having a processor, a memory, and one or more input/output (I/O) ports, the I/O ports communicating with the one or more sensors, the one or more remote servers, the vehicle, and the HMI, wherein the BCE application further includes control logic comprising:
performing local data collection from the one or more sensors of the vehicle, including:
determining a charging status of the battery of the vehicle;
upon determining that the battery is currently being charged, continuing to monitor the charging status of the battery; and
upon determining that the battery is not currently being charged, causing the one or more sensors to begin measuring dynamic battery information during an operation or cycle of the vehicle; and
at a completion of the operation or cycle of the vehicle, causing the one or more sensors to stop measuring dynamic battery information, and storing an operation or cycle time defining a duration of the operation or cycle, wherein the dynamic battery information further comprises: a voltage (V), a current (I), and a temperature (T) of the battery;
determining whether a state of charge (SoC) of the battery is zero;
upon determining that the SoC of the battery is greater than zero, continuing to monitor the SoC of the battery until the SoC of the battery is equal to zero;
upon determining that the SoC of the battery is equal to zero, charging the battery and integrating current (I) until a state of charge of the battery is equal to 1; and
upon determining that the state of charge of the battery is equal to one, generating a full original battery capacity based on integration of the current (I);
transmitting the data collected by the one or more sensors to the one or more cloud-computing servers, and for performing within the one or more cloud-computing servers, data conversion of the data collected by the one or more sensors, and training a data-driven BCE model with data converted from the data collected by the one or more sensors, wherein the data conversion reduces a size of the data collected by the one or more sensors over time from a first size to a second size substantially smaller than the first size, wherein the data conversion removes a time-dependency of the data from the one or more sensors, wherein the data conversion and training further comprise:
determining a quantity of data sets available for training;
defining sizes of partitions for a voltage (V), a current (I), and a temperature (T) of the battery; and
calculating bins of the voltage (V), current (I), and temperature (T) of the battery, wherein the bins of the voltage (V), current (I), and temperature (T) of the battery are sized based on minimum and maximum values for each variable voltage (V), current (I), and temperature (T) of the battery, including control logic for obtaining voltage minimums and maximums (V_min, V_max) from battery specifications, current minimums and maximums (I_min, I_max) from battery performance data, temperature minimums and maximums (T_min, T_max) from battery operating condition information;
determining an optimal size of the bins by minimizing a performance index according to:
$$J = {\sum }_{k = 1}^{N} {{W}_{1} ( h ( {z}_{k} - {z}_{k - 1} ) )}^{2} + {W}_{2} N ; such that {z}_{0} = {V}_{min} , {z}_{N} = {V}_{max} for voltage ( V ) ; that {z}_{0} = {I}_{min} , {z}_{N} = {I}_{max} for current ( I ) , and that {z}_{0} = {T}_{min} , {z}_{N} = {T}_{max} for temperature ( T ) , {z}_{k} - {z}_{k - 1} > 0 ; N \leq {N}_{max} ∈ ℕ ;$$
where N is the number of bins, W is a weighting factor; and
stacking the bins of voltage (V), current (I), and temperature (T) of the battery with the time duration for the operation or cycle, and the full original battery capacity;
augmenting new data to existing data;
determining that data conversion is complete; and
training a data-driven BCE model by:
defining hidden layers and a quantity of step delays in the data-driven model;
utilizing one or more of a recurrent neural network (RNN), an autoregressive with non-linear input (ARX) model, and a nonlinear autoregressive exogenous (NARX) model; and
determining whether a battery capacity estimation error is less than a threshold error; and
wherein upon determining that the battery capacity estimation error is greater than or equal to the threshold, continuing to define hidden layers and quantities of step delays in the data-driven model and continuing to train the data driven model through one or more of RNN, ARX and NARX; and
wherein upon determining that the battery capacity estimation error is less than the threshold error, determining that the data-driven model design is complete; and
receiving, from the cloud-computing server, the data-driven model and
beginning a current battery capacity estimation including:
determining a charging status of the battery of the vehicle;
upon determining that the battery is currently being charged continuously monitoring the charging status of the battery;
upon determining that the battery is not currently being charged, causing the one or more sensors to begin measuring dynamic battery information during an operation or cycle of the vehicle;
at a completion of the operation or cycle of the vehicle, causing the one or more sensors to stop measuring dynamic battery information, and store an operation or cycle time defining a duration of the operation or cycle;
calculating bins of voltage (V), current (I), and temperature (T) of the battery according to the data-driven model design;
stacking the bins of voltage (V), current (I), and temperature (T) of the battery with the time duration for the operation or cycle, and the full original battery capacity;
predicting the current battery capacity with the data-driven model; and
wherein upon predicting the current battery capacity with the data driven model, generating a notification to the vehicle occupants, by the controller via the HMI, including the current battery capacity estimate, and sharing the current battery capacity estimate with the additional vehicle sub-systems utilizing accurate battery SoC estimations.
